(19) United States
(12) Patent Application Publication
(10) Pub. No.: US 2020/0335383 A1
(43) Pub. Date: Oct. 22, 2020

(54) MICRO DEVICE TRANSFERRING APPARATUS AND METHOD FOR TRANSFERRING MICRO DEVICE

(71) Applicant: XIAMEN SANAN OPTOELECTRONICS TECHNOLOGY CO., LTD., XIAMEN (CN)

(72) Inventors: CHEN-KE HSU, XIAMEN (CN); ZHIBAI ZHONG, XIAMEN (CN); CHIA-EN LEE, XIAMEN (CN); JINJIAN ZHENG, XIAMEN (CN); ZHENG WU, XIAMEN (CN); SHAO-YING TING, XIAMEN (CN)

(21) Appl. No.: 16/903,829

(22) Filed: Jun. 17, 2020

Related U.S. Application Data
(63) Continuation-in-part of application No. PCT/CN2018/087802, filed on May 22, 2018.

(30) Foreign Application Priority Data
Dec. 26, 2017 (CN) 201711426885.1

(51) Int. Cl. H01L 21/683; H01L 21/677

(52) U.S. Cl. CPC H01L 21/6836; H01L 2221/68368; H01L 21/67706

(57) ABSTRACT

A micro device transferring apparatus includes a first conveying mechanism, a carrier unit, a push device and a release device. The first conveying mechanism includes a release tape having a release adhesive, a first roller connected to an end of the release tape, and a conveying device connected to a horizontal section of the release tape to drive the release tape to move in a moving direction. The carrier unit includes a first carrier holding multiple micro devices, and a second carrier for receiving the micro devices. The push device is for pushing the release tape to pick up the micro devices with the release adhesive. The release device is for decomposing the release adhesive to release the micro devices.

### CROSS-REFERENCE TO RELATED APPLICATION

This application is a bypass continuation-in-part application of PCT International Application No. PCT/CN2018/087802 filed on May 22, 2018, which claims priority to Chinese Patent Application No. 201711426885.1 filed on Dec. 26, 2017. The entire content of the international application is incorporated herein by reference.

### FIELD

The disclosure relates to a micro device transferring technique, and more particularly to a micro device transferring apparatus and a method for transferring at least one micro device.

### BACKGROUND

Conventionally, transferring of micro devices (e.g., micro LED chips, diode chips, transistor chips, IC chips, etc.) are usually enabled by van der Waals force, electrostatic adsorption, phase transformation, and laser ablation, in which van der Waals force, electrostatic adsorption and laser ablation are most commonly used.

Another commonly used technique is thermal release adhesive. A suction head is used to suck the thermal release adhesive, after which the thermal release adhesive is used to pick up the chip, followed by moving the chip to be aligned with a substrate. Afterwards, the thermal release adhesive is heated to release the chip onto the substrate. However, the thermal release adhesive is not reusable after heated, and such transfer process requires high precision when picking up the chip and when releasing the chip, which may be rather inefficient. Transfer printing techniques may also be used for transferring the chip. However, the printing pattern is pre-determined, and requires complicated steps to alter.

Therefore, it is desirable in the art to provide a way of efficiently and precisely transferring micro devices.

### SUMMARY

Therefore, a first aspect of the present disclosure provides a micro device transferring apparatus that can alleviate at least one of the drawbacks of the prior art.

The micro device transferring apparatus includes a first conveying mechanism, at least one carrier unit, a push mechanism, and a release mechanism.

The release tape has a first end, a second end opposite to the first end, a horizontal section disposed between the first and second ends, a tape substrate, and a release adhesive connected to a side surface of the tape substrate. The first roller is connected to the first end of the release tape. The conveying device is connected to the horizontal section of the release tape and is operable to drive the horizontal section of the release tape to move in a moving direction. The carrier unit is disposed under the horizontal section of the release tape, and includes a first carrier that is adapted for holding a plurality of micro devices, and a second carrier that is spaced apart from the first carrier in the moving direction and that is adapted for receiving the micro devices transferred from the first carrier. The push mechanism includes a push device that is movable in a vertical direction and that is operable for pushing the release tape toward the first carrier such that the release adhesive comes into contact with at least one of the micro devices to pick up the at least one of the micro devices. The release mechanism includes a release device operable for decomposing a part of the release adhesive of the release tape to release the at least one of the micro devices picked up by the release tape onto the second carrier.

A second aspect of the present disclosure provides a method of utilizing the micro device transferring apparatus of the first aspect for transferring at least one of the micro devices. The method includes:

operating the push device of the push mechanism to push the release tape such that the release adhesive of the release tape picks up the at least one of the micro devices;

operating the conveying device to move the release tape in the moving direction such that the at least one of the micro devices is moved to a position located above a second carrier; and

operating the release device of the release mechanism to decompose a part of the release adhesive of the release tape to release the at least one of the micro devices picked up by the release tape onto the second carrier.

### BRIEF DESCRIPTION OF THE DRAWINGS

Other features and advantages of the disclosure will become apparent in the following detailed description of the embodiment with reference to the accompanying drawings, of which:

FIG. 1 is a schematic view of an embodiment of a micro device transferring apparatus according to the present disclosure, in which a micro device is picked up by a release adhesive of a release tape of a first conveying mechanism of the embodiment;

FIG. 2 is a partially schematic view of the embodiment, in which the micro device is released onto a second carrier of a carrier unit of the embodiment;

FIG. 3 is a schematic view of a micro-adjustment unit of the embodiment for adjusting the orientation of a push surface of a push mechanism of the embodiment;

FIG. 4 is a schematic view showing a matrix of the micro devices to be transferred; and

FIG. 5 is a flow chart of major steps of a method for transferring the micro device.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

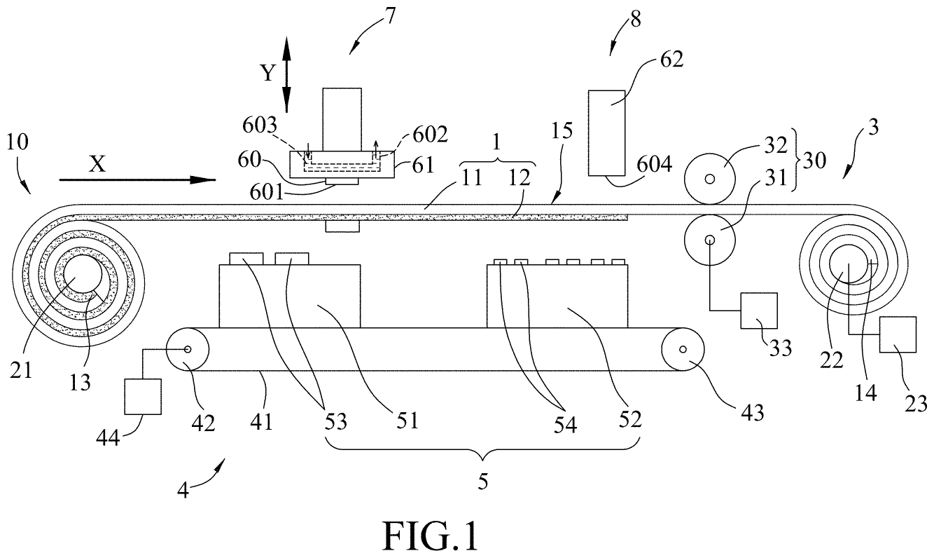

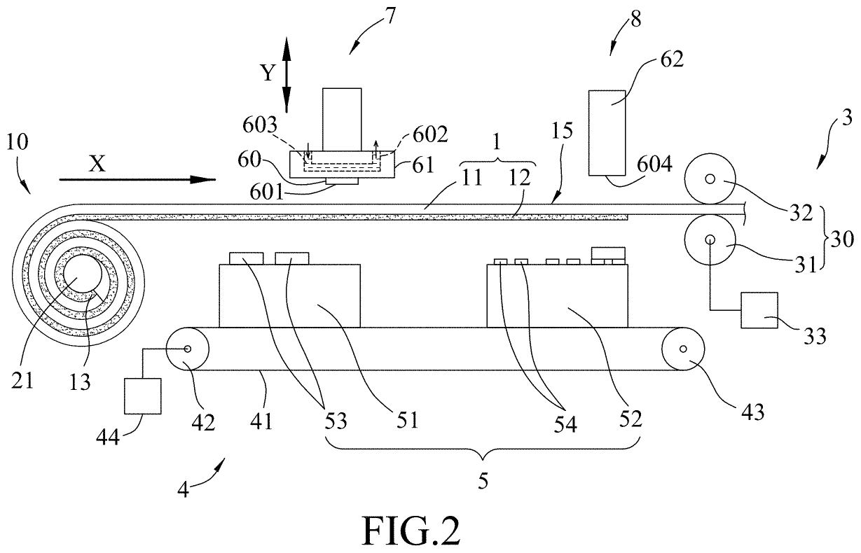

Referring to FIGS. 1 and 2, an embodiment of a micro device transferring apparatus is used for transferring at least one micro device 53. In this embodiment, the micro device 53 is exemplified as a micro LED chip, but may be other micro devices according to practical requirements.

The micro device transferring apparatus includes a first conveying mechanism 10, at least one carrier unit 5, a second conveying mechanism 4, a push mechanism 7 and a release mechanism 8.

The first conveying mechanism 10 includes a release tape 1, a first roller 21, a second roller 22, a roller driving device 23 and a conveying device 3. The release tape 1 has a tape substrate 11 and a release adhesive 12 connected to a side surface of the tap substrate 11. The release tape 1 further has a first end 13, a second end 14 opposite to the first end 13, a horizontal section 15 disposed between the first and second ends 13, 14. The first roller 21 is connected to the first end 13 of the release tape 1, and a portion of the release tape 1 is wrapped around the first roller 21. The second end 14 of the release tape 1 is connected to the second roller 22. The conveying device 3 is connected to the horizontal section 15 of the release tape 1 and is operable to drive the horizontal section 15 of the release tape 1 to move in a moving direction (X). In this embodiment, the conveying device 3 includes a pinch unit 30 including a driving roller 31 and a driven roller 32 that are disposed at two sides of the horizontal section 15 of the release tape 1 to pinch the horizontal section 15. The conveying device 3 further includes a pinch unit driving device 33 that is connected to the pinch unit 30 to drive rotation of the driving roller 31 to move the horizontal section 15 of the release tape 1 in the moving direction (X). In this embodiment, the pinch unit driving device 33 is a stepping motor. It should be noted that the pinch unit 30 may be changed or omitted according to practical requirements. In certain embodiments, the pinch unit 30 is omitted, and the roller driving device 23 is operable to drive rotation of the second roller 22 to move the horizontal section 15 of the release tape 1 in the moving direction (X). The second end 14 of the release tape 1 may be wound on the second roller 22, may be attached to the second roller 22, or may be connected to the second roller 22 via a clamping device. Gearsets may be provided to be coupled between the stepping motors and the rollers.

The carrier unit 5 is disposed under the horizontal section 15 of the release tape 1, and includes a first carrier 51 that is adapted for holding a plurality of the to-be-transferred micro devices 53, and a second carrier 52 that is spaced apart from the first carrier 51 in the moving direction (X) and that is adapted for holding a plurality of substrates 54, which are used for respectively receiving the micro devices 53 transferred from the first carrier 51.

The second conveying mechanism 4 is operable for moving the carrier unit 5 in the moving direction (X), and includes a conveying belt 41 that holds the carrier unit 5, a driving roller 42, a driven roller 43, and a control unit 44. The driving roller 42 and the driven roller 43 permit the conveying belt 41 to be disposed therearound. The control unit 44 drives rotation of the driving roller 42 to drive the conveying belt 41 and the driven roller 43, such that the conveying belt 41 carries the carrier unit 5 to move in the moving direction (X). In this embodiment, the conveying belt 41 is exemplified to be a stepping motor but may be changed according to practical requirements, and the gearsets may be provided to be coupled between the stepping motor and the rollers.

The push mechanism 7 includes a push device 61 that is movable in a vertical direction (Y) and that is operable for pushing the release tape 1 toward the first carrier 51 such that the release adhesive comes into contact with at least one of the micro devices 53 on the first carrier 51 to pick up the at least one of the micro devices 53. Specifically, the push device 61 has a bottom portion 60 that has a push surface 601 which is movable for pushing the release tape 1 and which is adapted to correspond in dimension to one of the micro devices 53 to transfer the micro devices 53 one at a time (see FIG. 1). It should be noted that the dimension of the push surface 601 of the push device 61 may be equal to or slightly larger than that of the micro device 53, and may be adjusted according to practical requirements. In certain embodiments, the push surface 601 of the push device 61 may correspond in dimension to a matrix of the micro devices 53, such as a 2×2 matrix as schematically shown in FIG. 4, for realizing batch transfer of the micro devices 53.

In this embodiment, a driver device (not shown) may be provided for controlling vertical movement of the push device 61. The driver device may be a pneumatic cylinder, a hydraulic cylinder, a robot hand, or an electric linear actuator which includes a ball screw mechanism or a rack-and-pinion mechanism.

Since the release adhesive 12 of the release tape 1 is usually not suitable to operate at high temperature, a cooling mechanism may be provided to the push mechanism 7. In certain embodiments, the push device 61 is made of a thermal conductive material (e.g., metal), and the push mechanism 7 further includes an internal passage 602 and a cold source 603 for introducing a cooling medium circulating through the internal passage 602 to cool the push device 61. The cold source 603 may be a circulating cooling water system.

The release mechanism 8 includes a release device 62 that is operable for decomposing a part of the release adhesive 12 of the release tape 1 to release the micro device 53 picked up by the release tape 1 onto the second carrier 52. In this embodiment, the release adhesive 12 of the release tape 1 is a thermal release adhesive, and the release device 62 is disposed above the horizontal section 15 of the release tape 1, and corresponds in position to the second carrier 52. The release device 62 may include, for example, an infrared heater to be operable to heat up the release adhesive 12 to decompose the release adhesive. In certain embodiments, the release device 62 may be made of thermal conductive metal, and may be provided with a heater, such as an electric heating device, for heating up the release device 62. Similar to the push mechanism 7, the driver device (not shown) may be provided to the release mechanism 8 to vertically move the release device 62 in the vertical direction (Y) to push the release tape 11. Also similar to the push mechanism 7, the release device 62 has a push surface 604 that is operable for pushing the release tape 1 and that corresponds in dimension to one of the micro devices 53. In certain embodiments, the push surface 604 of the release device 62 corresponds in dimension to a matrix of the micro devices 53.

In certain embodiments, the release adhesive 12 of the release tape 1 may be an ultraviolet release adhesive, and the release device 62 of the release mechanism 8 is operable to emit an ultraviolet light for decomposing the ultraviolet release adhesive. In certain embodiments, the release adhesive 12 of the release tape 1 may be a hydrodegradable adhesive, and the release device 62 of the release mechanism 8 is configured to be operable to decompose the hydrodegradable adhesive.

In certain embodiments, the micro device transferring apparatus may further include an adhesive coating device for applying adhesive onto the tape substrate 11 of the release tape 1 to form the release adhesive 12, allowing the release tape 1 to be reusable. The micro device transferring apparatus may further include a cleaning device for cleaning the tape substrate 11 before applying the adhesive. The tape substrate 11 may be infrared-penetrable to allow an infrared positioning mechanism to be adopted for increasing process precision. In this embodiment, the number of the carrier unit 5 is exemplified to be one. In certain embodiments, the micro device transferring apparatus may include a plurality of the carrier units 5 that are arranged on the conveying belt 41 of the second conveying mechanism 4 in the moving direction (X). When there are multiple carrier units 5, the first and second carriers 51, 52 may be alternately arranged, or all of the second carriers 52 may be arranged downstream of the first carriers 51. The first and second carriers 51, 52 may be fixedly or detachably connected to the second conveying mechanism 4, and are movable in the moving direction (X) by the second conveying mechanism 4. In certain embodiments, the second conveying mechanism 4 may be provided with a lifting device (not shown) to adjust the height of at least one of the first and second carriers 51, 52 of the carrier unit 5 relative to the release tape 1.

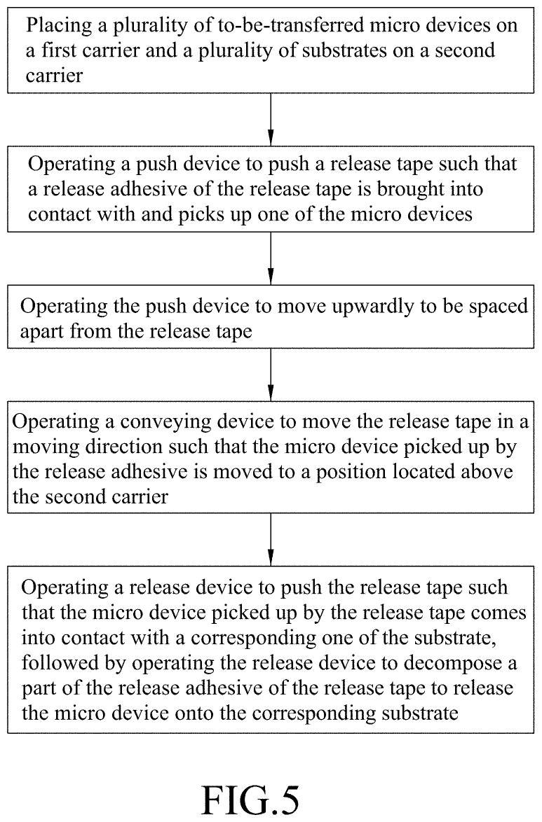

Referring to FIGS. 1, 2 and 5, a method of utilizing the micro device transferring apparatus for transferring at least one of the micro devices 53 includes:

placing a plurality of the to-be-transferred micro devices 53 on the first carrier 51 and a plurality of the substrates 54 on the second carrier 52;

operating the push device 61 to push the release tape 1 such that the release adhesive 12 of the release tape 1 is brought into contact with and picks up one of the micro devices 53;

operating the push device 61 to move upwardly to be spaced apart from the release tape 1;

operating the conveying device 3 to move the release tape 1 in the moving direction (X) such that the micro device 53 picked up by the release adhesive 12 is moved to a position located above the second carrier 52; and

operating the release device 62 to push the release tape 1 such that the micro device 53 picked up by the release tape 1 comes into contact with a corresponding one of the substrates 54, followed by operating the release device 62 to decompose a part of the release adhesive 12 of the release tape 1 to release the micro device 53 onto the corresponding substrate 54.

After the abovementioned steps, the first and second carriers 51, 52 can be advanced in the moving direction (X) for performance of the next micro device transfer process.

In this embodiment, the movement of the release tape 1 is controllable by the roller driving device 23, and the movement of the first and second carriers 51, 52 is controllable by the control circuit 44, thereby achieving precise positioning and rapid transferring.

In certain embodiments, a camera system (not shown), a horizontal actuating system (not shown) and a control system (not shown) may be provided to the micro device transferring apparatus. The camera system can capture the locations of the micro devices 53, and the horizontal actuating system can be operable to adjust the relative position of the push device 61 and the release device 62 in the moving direction (X) (i.e., at least one of the push device 61 and the release device 62 is movable in the moving direction (X)), ensuring the micro devices 53 are precisely aligned with respect to the substrates 54. The horizontal actuating system may be a robot hand. The image captured by the camera system can also be used for determining whether the movement of the release tape 1 of the first conveying mechanism 10 and the conveying belt 41 of the second conveying mechanism 4 are accurate. The control system is operable to adjust the movement of the release tape 1 and the conveying belt 41 to their proper speed and location.

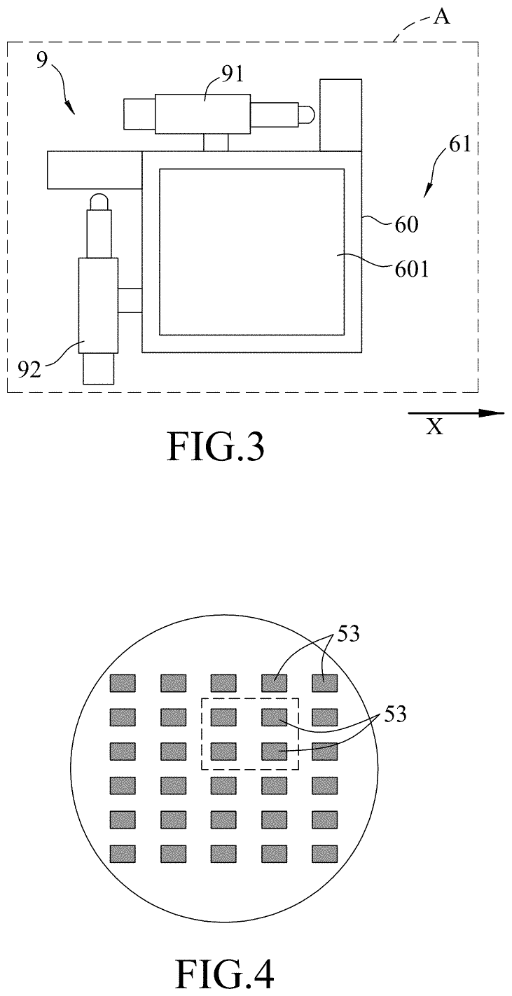

Referring to FIGS. 1 and 3, in certain embodiments, the micro device transferring apparatus further includes a micro-adjustment unit 9 for adjusting the orientation of at least one of the push surface 601 of the push mechanism 7 and the push surface 604 of the release mechanism 8 in an imaginary horizontal plane (A) extending in the moving direction (X). The micro-adjustment unit 9 includes an X-axis micro-adjustment member 91 connected to a side of the bottom portion 60 of the push device 61, and a Y-axis micro-adjustment member 92 connected to another side of the bottom portion 60 of the push device 61.

A combination of the push device 61, the release device 62 and the release adhesive 12 of the release tape 1 of the micro device transferring apparatus according to the present disclosure achieves precise and efficient transfer of the micro devices 53. This disclosure is also more flexible for its capability for transferring the micro devices 53 according to the number and arrangement of the substrates 54.

In the description above, for the purposes of explanation, numerous specific details have been set forth in order to provide a thorough understanding of the embodiments. It will be apparent, however, to one skilled in the art, that one or more other embodiments maybe practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiment but is intended to cover various arrangements included within the spirit and scope of the broadest interpretation so as to encompass all such modifications and equivalent arrangements.

What is claimed is:

1. A micro device transferring apparatus comprising:
a first conveying mechanism including
a release tape having a first end, a second end opposite to said first end, a horizontal section disposed between said first and second ends, a tape substrate, and a release adhesive connected to a side surface of said tape substrate,
a first roller connected to said first end of said release tape, and
a conveying device connected to said horizontal section of said release tape and operable to drive said horizontal section of said release tape to move in a moving direction;
at least one carrier unit disposed under said horizontal section of said release tape, and including
a first carrier adapted for holding a plurality of micro devices, and
a second carrier spaced apart from said first carrier in the moving direction, and being adapted for receiving the micro devices transferred from said first carrier;
a push mechanism including a push device that is movable in a vertical direction and that is operable for pushing said release tape toward said first carrier such that said release adhesive comes into contact with at least one of the micro devices to pick up the at least one of the micro devices; and
a release mechanism including a release device operable for decomposing a part of said release adhesive of said release tape to release the at least one of the micro devices picked up by said release tape onto said second carrier.

2. The micro device transferring apparatus as claimed in claim 1, wherein said conveying device includes:
a pinch unit including a driving roller and a driven roller that are disposed at two sides of said horizontal section of said release tape to pinch said horizontal section of said release tape; and
a pinch unit driving device connected to said pinch unit to drive rotation of said driving roller to move said horizontal section of said release tape in the moving direction.

3. The micro device transferring apparatus as claimed in claim 1, wherein:
said first conveying mechanism further includes a second roller;
said second end of said release tape is connected to said second roller; and
said first conveying mechanism further includes a roller driving device that is operable to drive rotation of said second roller such that apart of said release tape is wound on said second roller.

4. The micro device transferring apparatus as claimed in claim 2, wherein said pinch unit driving device of said conveying device is a stepping motor.

5. The micro device transferring apparatus as claimed in claim 3, wherein said roller driving device of said first conveying mechanism is a stepping motor.

6. The micro device transferring apparatus as claimed in claim 1, wherein said release adhesive of said release tape is a thermal release adhesive, and said release device of said release mechanism is operable to heat up said release adhesive of said release tape.

7. The micro device transferring apparatus as claimed in claim 1, wherein said release adhesive of said release tape is an ultraviolet release adhesive, and said release device of said release mechanism is operable to emit an ultraviolet light.

8. The micro device transferring apparatus as claimed in claim 1, wherein:
said push device of said push mechanism is made of a thermal conductive material; and
said push mechanism further includes a cold source for cooling said push device.

9. The micro device transferring apparatus as claimed in claim 1, further comprising a second conveying mechanism for moving said at least one carrier unit in the moving direction.

10. The micro device transferring apparatus as claimed in claim 9, wherein said second conveying mechanism includes
a conveying belt that holds said at least one carrier unit, and
a driving roller and a driven roller that permit said conveying belt to be disposed therearound.

11. The micro device transferring apparatus as claimed in claim 10, wherein said second conveying mechanism further includes a control unit for driving rotation of said driving roller of said second conveying mechanism.

12. The micro device transferring apparatus as claimed in claim 1, wherein said push device has a push surface that is movable for pushing said release tape and that is adapted to correspond in dimension to one of the micro devices.

13. The micro device transferring apparatus as claimed in claim 12, wherein said push surface of said push device corresponds in dimension to a matrix of said micro devices.

14. The micro device transferring apparatus as claimed in claim 1, wherein said release device of said release mechanism is movable in the vertical direction to push said release tape.

15. The micro device transferring apparatus as claimed in claim 14, wherein said release device has a push surface that is operable for pushing said release tape and that corresponds in dimension to one of the micro devices.

16. The micro device transferring apparatus as claimed in claim 15, wherein said push surface of said release device corresponds in dimension to a matrix of said micro devices.

17. The micro device transferring apparatus as claimed in claim 1, wherein said micro device transferring apparatus includes only one of said carrier unit.

18. The micro device transferring apparatus as claimed in claim 1, wherein said micro device transferring apparatus includes a plurality of said carrier units.

19. The micro device transferring apparatus as claimed in claim 1, wherein at least one of said push device of said push mechanism and said release device of said release mechanism is movable in the moving direction.

20. The micro device transferring apparatus as claimed in claim 12, further comprising a micro-adjustment unit for adjusting the orientation of said push surface of said push mechanism in an imaginary horizontal plane extending in the moving direction.

21. The micro device transferring apparatus as claimed in claim 15, further comprising a micro-adjustment unit for adjusting the orientation of said push surface of said release mechanism in an imaginary horizontal plane extending in the moving direction.

22. A method of utilizing the micro device transferring apparatus as claimed in claim 1 for transferring at least one of the micro devices, the method comprising:
operating the push device of the push mechanism to push the release tape such that the release adhesive of the release tape picks up the at least one of the micro devices;
operating the conveying device to move the release tape in the moving direction such that the at least one of the micro devices is moved to a position located above the second carrier; and
operating the release device of the release mechanism to decompose a part of the release adhesive of the release tape to release the at least one of the micro devices picked up by the release tape onto the second carrier.
